(19) United States
(12) Patent Application Publication
(10) Pub. No.: US 2007/0161165 A1
(43) Pub. Date: Jul. 12, 2007

(54) Systems and methods involving thin film transistors

(75) Inventors: Chun-Yen Liu, Zhubei City (TW); Chang-Ho Tseng, Tao-Yuan Hsien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Toppoly Optoelectronics Corp.

(21) Appl. No.: 11/330,962

(22) Filed: Jan. 12, 2006

(51) Int. Cl. H01L 21/84

(52) U.S. Cl. 438/151

(57) ABSTRACT

Systems and methods for enhancing performance of a hydrogenation treatment are provided. A representative system comprises a thin film transistor (TFT) comprising a substrate, a diffusion barrier layer positioned on the substrate, a pad layer positioned on the diffusion barrier layer, and a polysilicon layer positioned on the pad layer, a gate insulating layer positioned on the polysilicon layer. The thickness of the pad layer is equal to or less than the thickness of the diffusion barrier layer. The diffusion barrier layer retards hydrogen atoms from diffusing from the silicon layer.

### BACKGROUND OF THE INVENTION

1. Field of the Invention

The invention relates to thin film transistors (TFTs).

2. Description of the Prior Art

A TFT liquid crystal display (TFT-LCD) device, in contrast to other types of LCD devices, provides the perceived advantages of better portability, lower power consumption, and lower radiation. Thus, a TFT-LCD is widely used in various portable products, such as notebooks, personal data assistants (PDA), and video cameras.

Generally, a TFT-LCD includes a plurality of pixels, wherein each pixel incorporates three sub-pixels. One sub-pixel of each pixel typically includes at least one TFT for switching or driving the corresponding sub-pixel.

A TFT of a TFT-LCD incorporates a polysilicon layer as a channel region. Conventionally, such a TFT is formed on a glass substrate, and includes both a source region and a drain region contacting the channel region, and a gate electrode insulated from the channel region by a gate insulating layer. During fabrication of the TFT, an amorphous silicon layer is first formed, then a re-crystallization process is performed to crystallize the amorphous silicon layer so that the amorphous silicon layer becomes a polysilicon layer for serving as the channel region. Grain-boundary defects and in-grain defects often occur in the polysilicon layer. For example, defects such as dangling bonds and strained bonds can occur that can affect the quality of the polysilicon layer as the channel region.

To improve the quality of the polysilicon layer, a hydrogenation treatment may be performed so that nitrogen and hydrogen atoms can diffuse into the channel regions to passivate dangling bonds and/or strained bonds to repair such defects. Accordingly, the mobility, reliability, on/off current ratio, and leakage current can be improved. Ammonia (NH₃) plasma is generally used for performing the hydrogenation treatment because ammonia plasma can provide a large amount of nitrogen and hydrogen atoms. However, when performing the hydrogenation treatment, it can be difficult to maintain the hydrogen and nitrogen atoms in the polysilicon layer as these atoms tend to diffuse continuously into the layer under the polysilicon layer. Therefore, the hydrogenation treatment typically is performed for a long time in order to ensure that the required amount of hydrogen and nitrogen atoms are present in the polysilicon layer. In so doing, a channel region with improved quality can be attained. Generally, such a hydrogenation treatment requires 150-200 minutes to effectively hydrogenate the polysilicon layer for obtaining the channel region of desirable characteristics. This considerable amount of time involved in the hydrogenation treatment can adversely affect process cost and fabrication capacity.

### SUMMARY OF THE INVENTION

Systems and methods for enhancing performance of hydrogenation treatment are provided.

An embodiment of such a system comprises a TFT that comprises a substrate, a buffer layer positioned on the substrate for retarding diffusion of hydrogen atoms during the hydrogenation treatment, a silicon layer positioned on the buffer layer, a gate insulating layer positioned on the silicon layer and a gate electrode positioned on the gate insulating layer and above the channel region. The silicon layer comprises a channel region, a source region, and a drain region. The buffer layer comprises a nitride layer, wherein the nitride layer has a thickness of greater than 500 Å.

Another embodiment of such a system comprises a TFT that comprises a substrate; a diffusion barrier layer supported by the substrate; a pad layer adjacent to the diffusion barrier layer; and a silicon layer positioned on the pad layer, wherein the diffusion barrier layer retards hydrogen atoms from diffusing therein during the hydrogenation treatment such that the hydrogen atoms tend to remain in the silicon layer.

Another embodiment of such a system comprises a TFT that comprises a substrate; a gate electrode on the substrate; a gate insulating layer on the gate electrode and the substrate; an amorphous silicon layer comprising a channel region on a portion of the pad layer and above the gate electrode; and a source electrode and a drain electrode contacting the channel region and positioned on two ends of the amorphous silicon layer, wherein the gate insulating layer comprises a diffusion barrier layer positioned on the gate electrode and the substrate. The gate insulating layer further comprises a pad layer on the diffusion barrier layer. The pad layer has a thickness equal to or less than a thickness of the diffusion barrier layer.

An embodiment of a method for enhancing performance of a hydrogenation treatment comprises: forming a diffusion barrier layer on a substrate; forming a pad layer on the diffusion barrier layer, a thickness of the pad layer being equal to or less than a thickness of the diffusion barrier layer; forming a silicon layer on the pad layer; and performing a hydrogenation treatment to diffuse hydrogen atoms into the silicon layer, wherein the hydrogen atoms tend to remain in the silicon layer due to the diffusion barrier layer.

### BRIEF DESCRIPTION OF THE DRAWINGS

FIGS. 1-3 are schematic, section views of an embodiment of a TFT during an embodiment of a fabrication process.

FIG. 4 is a schematic view of an embodiment of an electronic device incorporating an embodiment of a TFT.

FIG. 5 is a hydrogen concentration vs. structure depth chart of hydrogenation treatments

FIG. 6A is a schematic, section view of a prior art TFT structure.

FIG. 6B is a schematic, section view of an embodiment of a TFT.

FIG. 7 is a schematic, section view of another embodiment of a TFT.

### DETAILED DESCRIPTION

Systems and methods involving thin film transistors are provided. In some embodiments, such a system comprises a TFT that incorporates a diffusion barrier layer under a silicon layer, such as a polysilicon or amorphous silicon layer. The diffusion barrier layer prevents some, if not all, nitrogen and hydrogen atoms from diffusing into the layer under the silicon layer. Thus, the nitrogen and hydrogen atoms tend to remain in the silicon layer during a hydrogenation treatment. Accordingly, defects that can be present in the silicon layer can be effectively passivated. Preventing diffusion of the hydrogen and nitrogen atoms also can improve performance of the hydrogenation treatment, such as by reducing fabrication time and associated processing costs.

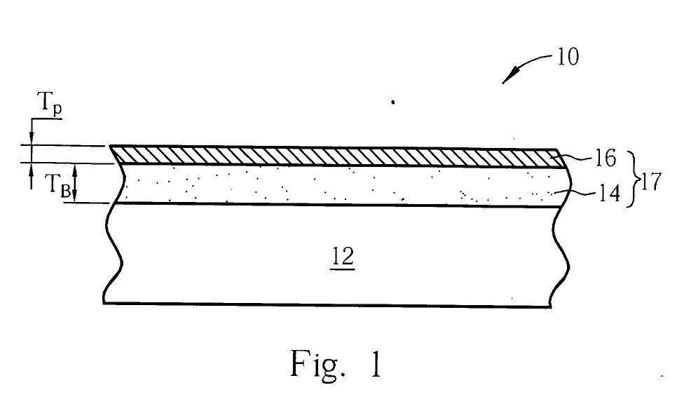

With reference to the drawings, FIGS. 1-3 are schematic, section views of an embodiment of a TFT during a fabrication process. As shown in these figures, TFT 10 is a low temperature poly-silicon (LTPS) TFT. During fabrication of the TFT 10, a substrate 12 is first provided, wherein the substrate 12 is a glass substrate or a quartz substrate. Then, a buffer layer 17 is formed on the substrate 12. In this embodiment of the present invention, the buffer layer 17 comprises a diffusion barrier layer 14 and a pad layer 16. The diffusion barrier layer 14 has a thickness T_{B} and the pad layer 16 has a thickness T_{P}, wherein the thickness T_{P} is equal to or less than the thickness T_{B}. The diffusion barrier layer 14 retards, and preferably prevents, hydrogen atoms from diffusing during a hydrogenation treatment. In this embodiment, the diffusion barrier layer has a thickness of greater than about 500 angstroms (Å).

Preferably, the diffusion barrier layer comprises silicon nitride (SiNₓ) such as Si₃N₄. The diffusion barrier layer may be formed by a low temperature deposition process that uses hexachlorodisilane (HCD, Si₂Cl₆) and monomethylamine (MMA) to form high quality Si₃N₄. The diffusion barrier layer can also be formed by a high temperature deposition process, a low pressure chemical vapor deposition (LPCVD) process, or a plasma chemical vapor deposition (PCVD) process.

The pad layer 16 preferably comprises silicon oxide (SiOₓ) because the interface of the SiOₓ/polysilicon is typically of good quality. Since the oxide pad layer 16 easily accepts hydrogen or nitrogen atoms during a hydrogenation treatment, thickness of layer 16 should be relatively thin, such as between approximately −100 and approximately 500 Å, and preferably between approximately 100 to approximately 300 Å. Please note that the material of the diffusion barrier layer 14 is not limited to silicon nitride and may comprise any materials that can effectively block hydrogen atoms and nitrogen atoms from diffusing during a hydrogenation treatment. Therefore, if the diffusion barrier layer 14 has a material that can provide a good interface between the diffusion barrier layer 14 and a silicon layer, the pad layer 16 may be omitted.

The pad layer 16 provides a preferable interface with a silicon layer. This is because the interface properties of SiOₓ/polysilicon are typically better than the interface properties of SiNₓ/polysilicon. Therefore, the pad layer 16 can provide an interface with the silicon layer exhibiting fewer defects, thus potentially avoiding extra leakage currents or decreasing on currents.

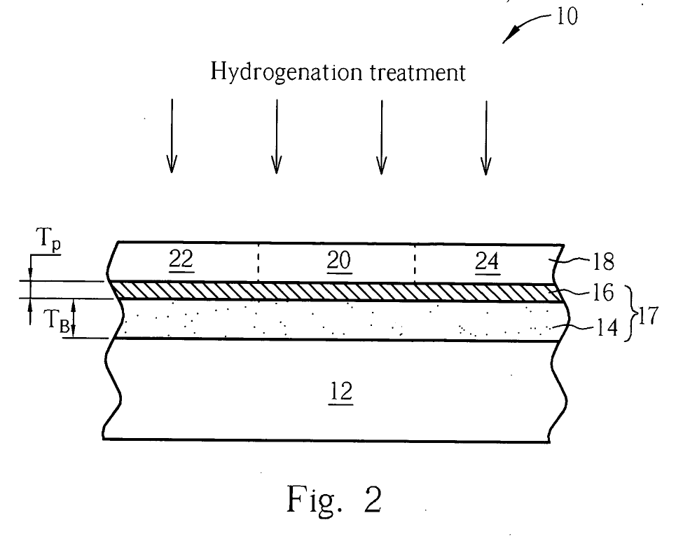

FIG. 2 shows an amorphous layer deposited on the buffer layer 17. A re-crystallization process is then performed to make the amorphous layer a polysilicon layer 18. The re-crystallization process may be carried out by an excimer laser crystallization (ELC) process, a metal induced lateral crystallization (MILC) process, or a solid-state crystallization process.

A channel region 20, a source region 22, and a drain region 24 are defined in the polysilicon layer 18. A hydrogenation treatment such as a high-pressure water vapor treatment is then performed to make hydrogen and nitrogen atoms diffuse into the polysilicon layer. Since the pad layer 16 is very thin and a thick diffusion barrier layer 14 is positioned below the pad layer 16, hydrogen and nitrogen atoms should be retarded, e.g. prevented, from diffusing into the pad layer 16. Therefore, most hydrogen and nitrogen atoms remain in the polysilicon layer 18. Additionally, the hydrogen and nitrogen atoms can bond with dangling bonds and strained bonds to repair defects of the polysilicon layer 18. Accordingly, the hydrogenation treatment such as a the high-pressure water vapor treatment can be applied for a short time while still achieving an improved quality of the channel region 20 of the polysilicon layer 18. In other embodiments, the hydrogenation treatment may be performed after the whole structure of the TFT 10 is formed.

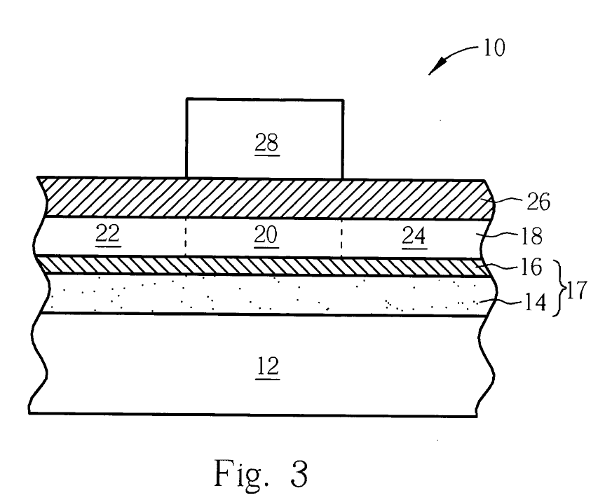

As shown in FIG. 3, a gate insulating layer 26 comprising oxide and a first conductive layer are formed on the polysilicon layer 18 after a first photo-etching process for patterning the polysilicon layer 18. The first conductive layer may be formed of various metals. Sequentially, a second photo-etching process is performed to pattern the first conductive layer and form a gate electrode 28 above the channel region 20. Then, an ion implantation process is selectively performed by using the gate electrode 28 as a mask to dope ions into the source region 22 and the drain region 24.

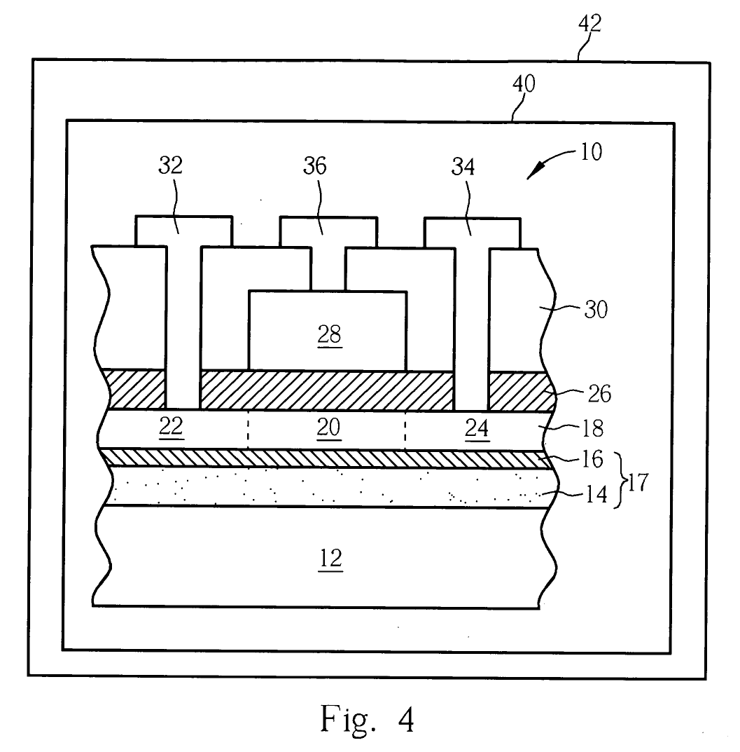

FIG. 4 shows a dielectric layer 30 formed on the gate electrode 28 and the gate insulating layer 26. A third photo-etching process is performed to form a plurality of contact holes through the dielectric layer 30 on the source region 22, the drain region 24 and the gate electrode 28. Then, a second conductive layer is formed and filled into these contact holes. Sequentially, a fourth photo-etching process is performed to etch the second conductive layer and form a first contact plug 32, a second contact plug 34, and a third contact plug 36 that are electrically connected to the source region 22, the drain region 24, and the gate electrode 28 respectively. FIG. 4 also shows that TFT 10 can be incorporated into a display (in this case, display 40) that can be an LCD display. The display can form a portion of a variety of electronic devices (in this case, electronic device 42). The electronic device can be a mobile phone, notebook, personal data assistant (PDA), car TV, or digital camera.

It should be noted that the diffusion barrier layer 14, which is composed of materials for preventing diffusion of hydrogen and nitrogen atoms, is thick enough so a greater amount of hydrogen and nitrogen atoms can remain in the polysilicon layer 18 during processing. This can improve the quality of the polysilicon layer 18 and therefore the channel region 20.

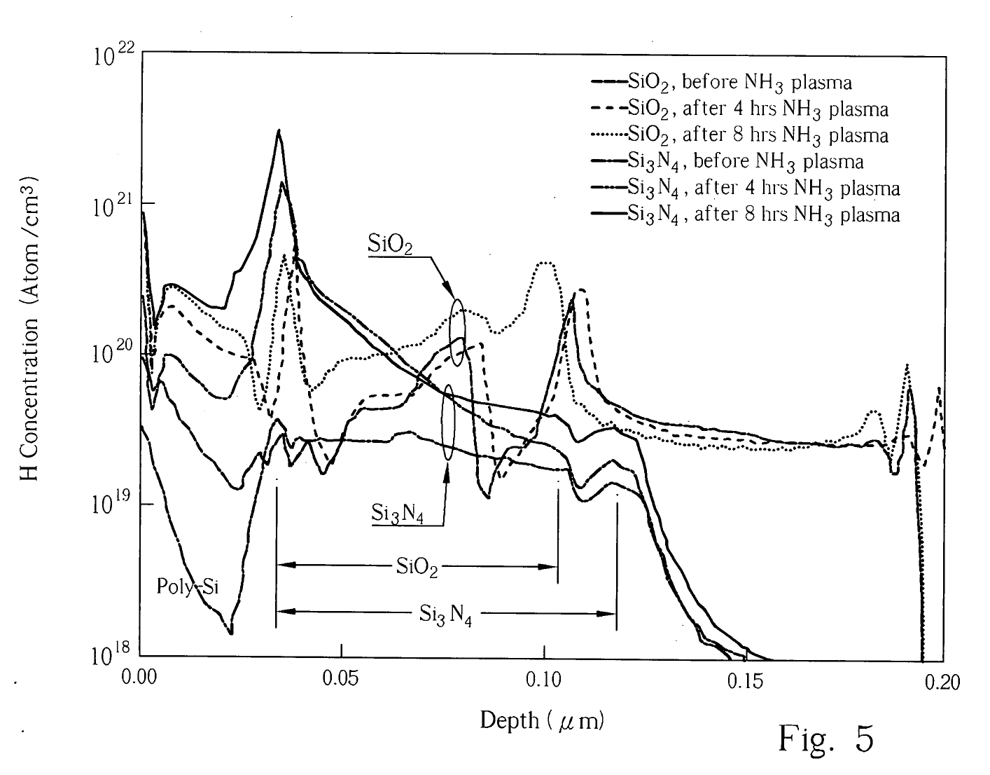

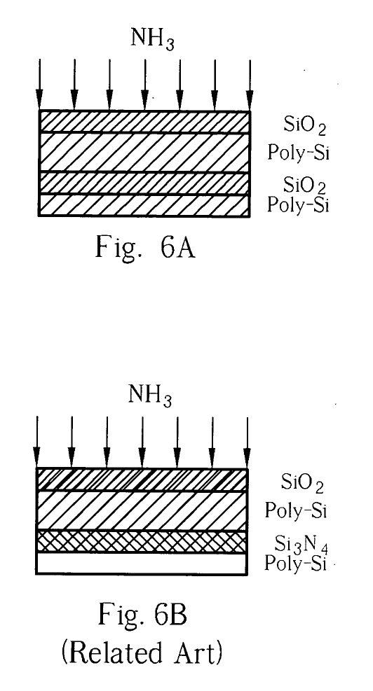

The performance of the diffusion barrier layer 14 is further described with respect to FIG. 5, which is a hydrogen concentration vs. structure depth chart of hydrogenation treatments. Additionally, the prior art structure depicted in FIG. 6(A) includes a first silicon oxide layer, a first polysilicon layer, a second silicon oxide layer, and a second polysilicon layer (shown from top to bottom). Referring to the chart, it can be seen that the hydrogen concentration in the first polysilicon layer is very low before a hydrogenation treatment. After four hours of hydrogenation treatment with ammonia plasma, the hydrogen concentration is raised but still has a lowest concentration in the first polysilicon layer of about 4×10¹⁹ atom/cm³ at a depth of about 0.025 μm of the structure of FIG. 6(A). The hydrogen concentration in the first polysilicon layer still has a lowest concentration of about 4.5×10¹⁹ atom/cm³ after eight hours of hydrogenation treatment. The reason for the non-uniform and low hydrogen concentration in the structure of FIG. 6(A) is that hydrogen atoms diffuse into the second silicon oxide layer and the second polysilicon layer. The effect can be understood by referring to the curves because the hydrogen concentration in the second oxide layer region (the depth of about 0.035 to 0.10 μm) and the second polysilicon layer (the depth of more than 0.10 μm) are very high.

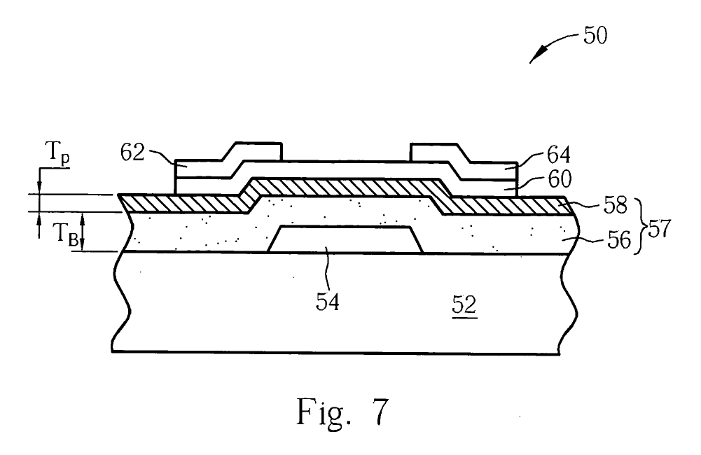

In contrast, the structure of FIG. 6(B) includes a silicon oxide layer, a first polysilicon layer, a silicon nitride layer, and a second polysilicon layer (shown from top to bottom). After four hours of hydrogenation treatment, the depth 0.025 μm of the structure of FIG. 6(B), which was the depth having the lowest hydrogen concentration in the structure of FIG. 6(A), has a high hydrogen concentration of about 1.8×10²⁰ atom/cm³ in the first polysilicon layer. The silicon nitride layer and the second polysilicon layer only have low hydrogen concentrations. After 8 hours of hydrogenation treatment, the result is the same and the first polysilicon layer has an even higher hydrogen concentration. Accordingly, the silicon nitride layer (the diffusion barrier layer) blocks hydrogen and nitrogen atoms from diffusing from an upper layer, such as the first polysilicon layer, into a lower layer, such as the second polysilicon layer. Please refer to FIG. 7, which is a schematic, section view of a TFT 50 according to another embodiment of the present invention. The TFT 50 is a bottom-gate TFT comprising a substrate 52, a patterned gate electrode 54 on the substrate 52, and a gate insulating layer 57 covering the gate electrode 54 and the substrate 52. It should be noted that the gate insulating layer 57 comprises a diffusion barrier layer 56. The diffusion barrier layer 56 preferably comprises silicon nitride (SiNₓ), and more preferably comprises Si₃N₄ for preventing nitrogen or hydrogen atoms from diffusing from an upper layer. In this embodiment, the diffusion barrier layer 56 has a thickness TB of more than 500 Å for providing the desired performance. The gate insulating layer 57 further comprises a pad layer 58 positioned on the diffusion barrier layer 56, that is made of silicon oxide. Since a silicon oxide layer may easily accept nitrogen and hydrogen atoms, the pad layer 58 should be very thin—about 100-500 Å, and preferably about 100-300 Å. Therefore, the thickness T_{P} of the pad layer 58 is equal to or less than the thickness T_{B} of the diffusion barrier layer 56.

The TFT 50 further comprises an amorphous silicon layer 60 serving as the channel region on a portion of the gate insulating layer 57, above the gate electrode 54. Furthermore, the TFT 50 comprises a source electrode 62 and a drain electrode 64 contacting the amorphous silicon layer 60 and positioned on two ends of the amorphous silicon layer 60.

Having thus described several exemplary embodiments, TFTs such as those described, incorporate diffusion barrier layers positioned under the polysilicon layer or the amorphous silicon layer so that hydrogen and nitrogen atoms can be retained in the polysilicon layer or the amorphous silicon layer during a hydrogenation treatment to improve the quality of the layer as a result, a time duration of the hydrogenation treatment can be reduced compared to conventional processes. By reducing the time duration of the hydrogenation treatments, the fabrication process can be conducted more quickly and a resultant amount of formed TFTs can be increased. Additionally, such TFTs can exhibit better mobility, reliability, on/off current ratio, and leakage current.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A system for enhancing performance of a hydrogenation treatment, comprising:
a thin film transistor (TFT) comprising:
a substrate;
a diffusion barrier layer supported by the substrate;
a pad layer adjacent to the diffusion barrier layer, a thickness of the pad layer being equal to or less than a thickness of the diffusion barrier layer; and
a silicon layer positioned on the pad layer;
wherein the diffusion barrier layer retards hydrogen atoms from diffusing therein during the hydrogenation treatment such that the hydrogen atoms tend to remain in the silicon layer.

2. The system as claimed in claim 1, wherein the silicon layer is a polysilicon layer or an amorphous silicon layer.

3. The system as claimed in claim 1, wherein the diffusion barrier layer comprises silicon nitride (SiNₓ).

4. The system as claimed in claim 3, wherein the diffusion barrier comprises Si₃N₄.

5. The system as claimed in claim 1, wherein the diffusion barrier layer has a thickness of greater than about 500 angstroms (Å).

6. The system as claimed in claim 1, wherein the pad layer comprises silicon oxide (SiOₓ).

7. The system as claimed in claim 1, wherein the pad layer has a thickness in a range of about 100 Å to about 500 Å.

8. The system as claimed in claim 1, wherein the pad layer has a thickness in a range of about 100 Å to about 300 Å.

9. The system as claimed in claim 1, wherein the system comprises: a display device operative to display images, the display device comprising the TFT.

10. The system as claimed in claim 9, wherein the display device is a liquid crystal display device.

11. A system for enhancing performance of a hydrogenation treatment comprising:
a thin film transistor (TFT) comprising:
a substrate;
a buffer layer supported by the substrate for retarding diffusion of hydrogen atoms into the buffer layer and substrate during the hydrogenation treatment, the buffer layer comprising a nitride layer having a thickness of greater than about 500 Å;
a silicon layer supported by the buffer layer, the silicon layer comprising a channel region, a source region, and a drain region;
a gate insulating layer supported by the silicon layer; and
a gate electrode positioned on the gate insulating layer and above the channel region.

12. The system as claimed in claim 11, wherein the silicon layer is a polysilicon layer or an amorphous silicon layer.

13. The TFT as claimed in claim 11, wherein the nitride layer comprises silicon nitride (Si₃N₄).

14. The system as claimed in claim 11, wherein the buffer layer further comprises an oxide layer.

15. The system as claimed in claim 14, wherein the oxide layer has a thickness in a range of about 100 Å to about 500 Å.

16. A system for that enhancing performance of a hydrogenation treatment comprising:
a substrate;
a silicon layer supported by the substrate; and
means, disposed between the silicon layer and the substrate, for preventing diffusion of hydrogen atoms from the silicon layer during the hydrogenation treatment.

17. The system as claimed in claim 16, further comprising a gate electrode located above the silicon layer.

18. The system as claimed in claim 17, wherein the means for preventing diffusion further comprises a pad layer positioned on a diffusion barrier layer, the diffusion barrier layer comprising silicon nitride (SiNx), the pad layer having a thickness equal to or less than a thickness of the diffusion barrier layer.

19. The system as claimed in claim 18, wherein the system comprises a thin film transistor (TFT); wherein the substrate and the gate electrode form at least a portion of the TFT.

20. The system as claimed in claim 19, wherein the TFT is a low temperature polysilicon (LTPS) TFT.

21. The system as claimed in claim 18, wherein the silicon layer comprises a channel region, a source electrode and a drain electrode.

22. The system as claimed in claim 21, wherein the pad layer comprises silicon oxide (SiOₓ).

23. A method for enhancing performance of a hydrogenation treatment, comprising:
forming a diffusion barrier layer on a substrate;
forming a pad layer on the diffusion barrier layer, a thickness of the pad layer being equal to or less than a thickness of the diffusion barrier layer;
forming a silicon layer on the pad layer; and
performing a hydrogenation treatment to diffuse hydrogen atoms into the silicon layer, wherein the hydrogen atoms tend to remain in the silicon layer due to the diffusion barrier layer.
